(19) United States
(12) Patent Application Publication
(10) Pub. No.: US 2006/0131742 A1
(43) Pub. Date: Jun. 22, 2006

(54) PACKAGED CHIP CAPABLE OF LOWERING CHARACTERISTIC IMPEDANCE

(75) Inventor: Chung-Hsing Tzu, Zhonghe City (TW)

Correspondence Address: BIRCH STEWART KOLASCH & BIRCH, PO BOX 747, FALLS CHURCH, VA, 22040-0747, US

(73) Assignee: Fine Tech. Inc.

(21) Appl. No.: 11/057,132

(22) Filed: Feb. 15, 2005

(30) Foreign Application Priority Data
Dec. 16, 2004 (TW) 093220255

(51) Int. Cl. H01L 23/34

(52) U.S. Cl. 257/728

(57) ABSTRACT

A packaged chip lowering characteristic impedance comprises a chip, a lead wire frame, a plurality of metal layers, adhesive layers, lead wires, and a mold, being formed into TSOP LOC and thin-small-sized packaging types; from a specified site above or under each row of leads of the lead wire frame, metal layers are fixed respectively with adhesives layers to the lead wire frame; lead wires are connected respectively between electrode contacts of the chip and leads of the lead wire frame and a lead wire provided is connected between at least one lead and the metal layer, so the packaged chip using metal layers as a Ground or Power plane is formed; thus, electrical noises and EMI are lowered and a problem of poor transmission of signals is eliminated so that a stable transmission of signals and an efficient transmission speed may be further developed.

### FIELD OF THE INVENTION

This invention relates to a packaged chip capable of lowering characteristic impedance and particularly to an improvement of structures of a thin-small-outline-package lead-on-chip (TSOP LOC) type and thin-small-outline-package and quad flat pack (TSOP and QFP) types.

### BACKGROUND OF THE INVENTION

A conventional chip packaging types are generally a thin-small-outline-package or a quad flat pack type (TSOP or QFP as shown in FIG. 8) and a thin-small-outline-package lead-on-chip (TSOP LOC as shown in FIG. 7) in structure and both of the two structures have chips 10 and 10′ on which lead wire frames 20 and 20′ outward conductive are provided; the lead wire frame 20 is a metallic material stamped into 2 or 4 rows of a plurality of arranged leads 201 and 201′, and thereby bonding wires 40 and 40′ electrically connected to each other are provided between the plurality of leads 201 and 201′ of electrode contacts and lead wire frames 20 and 20′ of the chips 10 and 10′ around which insulating sealing colloids (mold) 50 and 50′ are provided so that a conventional chip packaging type is formed, in which the difference of TSOP or QFP from TSOP LOC lies in only that the latter has the chip 10 direct mount with an adhesive below the lead wire frame 20 and the size of chip is thereby reduced.

From the mentioned-above disclosed chip TSOP or QFP and TSOP LOC types, solutions to Electromagnetic Interference (EMI) and noises, including a shot noise, a flicker noise, a surge noise, a thermal noise, an allocation noise and the like, often caused in electronic products are not described, and a problem of poor transmission of signals resulting from characteristic impedance of a packaged body is not eliminated, with the result that the requirements of strict EMC and high transmission efficiency of the current electronic products are difficultly met.

### SUMMARY OF THE INVENTION

This invention is mainly to provide a packaged chip capable of lowering characteristic impedance and particularly lowers electrical noises and EMI with a designed metal layer of structure at a specified area of a lead-wire frame, namely with an improved lead wire connection structure and may eliminate a problem of poor transmission of signals resulting from characteristic impedance of a packaged body so that the stable transmission of signals and the efficient transmission speed may be further developed.

From the object mentioned above, according to an embodiment of this invention, a chip, a lead wire frame, a plurality of metal layers, adhesive layers, lead wires, and a mold are structured and molded into TSOP LOC and thin-small-sized packaging (including TSOP and QFP) types; thereby, from a specified site above or under each row of leads of the lead wire frame, metal layers are fixed respectively with adhesive layers to the lead wire frame, lead wires are connected respectively between a plurality of electrode contacts of the chip and leads of the lead-wire frame, and a lead wire provided is connected between at least a lead and the metal layer, thereby the improved structure of packaged chip capable of lowering characteristic impedance according to this invention being formed; with the metal layer used as a ground or power plane and with the structure of the metal layer connected to the lead with the lead wire, the electrical noises and EMI are lowered and the problem of poor transmission of signals resulting from characteristic impedance of the packaged body is eliminated.

### BRIEF DESCRIPTION OF THE DRAWINGS

FIG. 1 is a cross-sectional view illustrating a thin-small-outline-package lead-on chip (TSOP LOC) according to this invention;

FIG. 2 is a cross-sectional view illustrating the thin-small-outline-package lead-on chip (TSOP LOC) according to another embodiment of this invention;

FIG. 3 is a cross-sectional view illustrating a thin-small sized (TSOP or QFP) chip according to this invention;

FIG. 4 is a cross-sectional view illustrating the thin-small sized (TSOP or QFP) chip according to another embodiment of this invention;

FIG. 5 is a top view illustrating the thin-small-outline-package lead-on chip (TSOP LOC) according to this invention;

FIG. 6 is a top view illustrating the thin-small sized (TSOP or QFP) chip according to this invention;

FIG. 7 is a view of a conventional thin-small-outline-package lead-on chip (TSOP LOC); and

FIG. 8 is a view of a conventional thin-small sized chip.

### DETAILED DESCRIPTION OF THE PREFERRED EMBODIMENTS

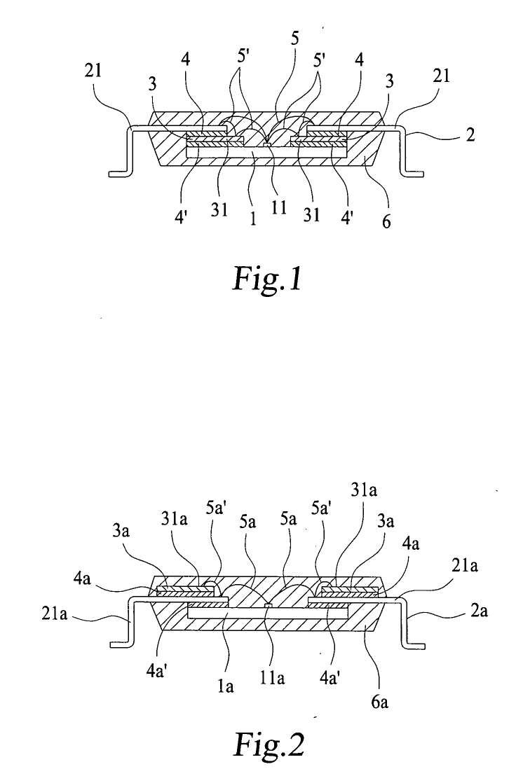

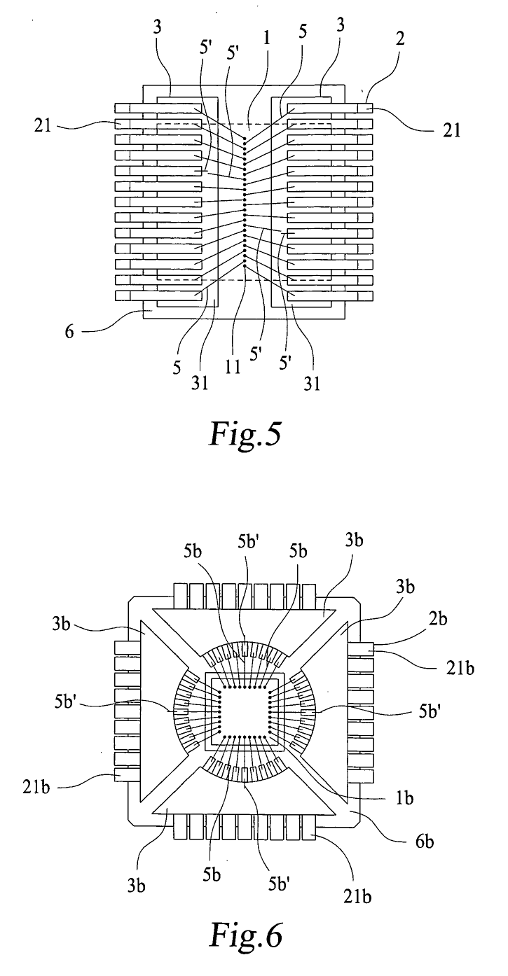

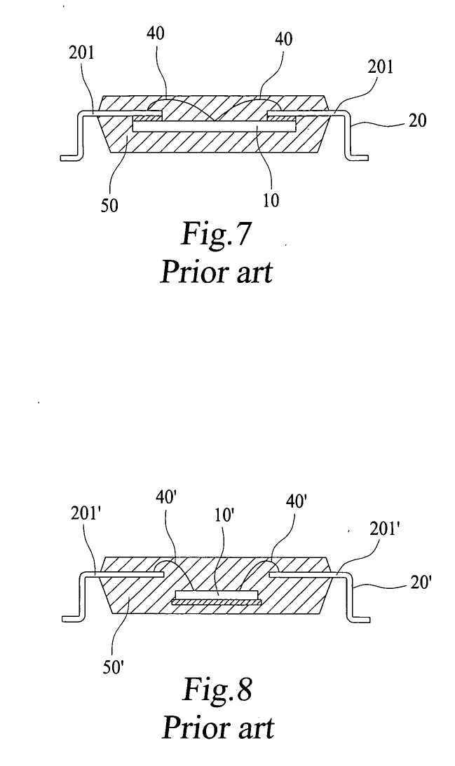

Referring now to FIGS. 1 and 5, this invention is a packaged chip capable of lowering characteristic impedance, comprising a chip 1, a lead wire frame 2, a plurality of metal layers 3, adhesive layers 4 and 4′, lead wires 5 and 5′, and a mold 6, in which the chip 1 is a specifically functional electronic element made of silicon or GaAs semiconductor material and a plurality of electrode contacts 11 are provided at a specified site; the lead wire frame 2 is structured with metallic materials stamped into 2 or 4 rows (QFP type) of a plurality of leads 21 to serve as the outward electrically connecting elements of the chip 1; the metal layers 3 are metallic tablets, films, or nets, or other conductive tablets; the adhesive layers 4 and 4′ may be formed into adhesive solid substances (glue and the like) or adhesive tapes after they are dried from the liquid state; the lead wires 5 and 5′ are metallic or conductive wires; and the mold 6 is an insulator wrapping the formerly described elements of the chip 1;

thereby, the chip 1, the lead wire frame 2, the metal layers 3, the adhesive layers 4 and 4′, the lead wires 5 and 5′, and the mold 6 are structured into the TSOP LOC; as shown in FIGS. 1 and 5, an adhesive layer 4 is provided under each row of leads 21 of the lead wire frame 2 to stick to a metal layer 3, so a wire bonding area 31 is reserved on the metal layer 3, and another adhesive layer 4′ is provided under the metal layer 3 to stick to the chip 1; the lead wire 5 is thereby connected between the plurality of electrode contacts 11 of the chip 1 and the leads 21 of the lead-wire frame 2, at least one electrode contact 11 is selected and connected first to the bonding area 31 of the metal layer 3 with the lead wire 5′ and next to the lead 21 with the lead wire 5′, the mold 6 is used to wrap the chip 1 and the metal layer 3, and thereby the packaged chip capable of lowering characteristic impedance.

Referring now to FIG. 2, according to TSOP LOC of this invention, adhesive layers may also be provided above (or both above and below) each row of leads 21a of a lead wire frame 2a to respectively stick to metal layers 3a so that a wire bonding area 31a is reserved on the metal layer, and another adhesive layer 4a′ is provided under each row of leads 21a of the lead wire frame 2a to stick to the chip 1a; thereby, a lead wire 5a is connected between a plurality of electrode contacts 11a of the chip la and leads 21a of the lead-wire frame 2a, a lead wire 5a′ is connected between at least a lead 21a and the wire bonding area 31a of metal layer 3a, and next a mold 6a is used to wrap the chip 1a and the metal layer 3a.

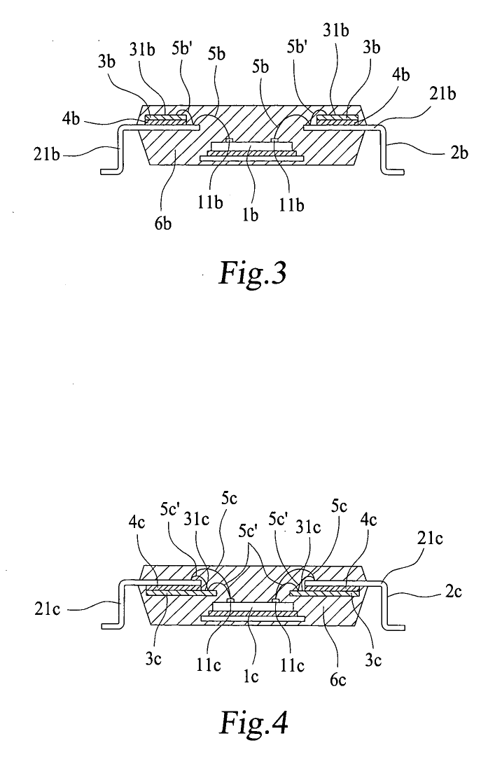

Next, this invention may also be formed into a thin-small size packaging (including TSOP and QFP) types, referring now to FIGS. 3 and 6; namely, adhesive layers 4b respectively sticking to metal layers 3b are provided above 2 or 4 rows of leads 21b of a lead wire frame 2b so that a wire bonding area 31b is reserved on the metal layer 3b, and the chip 1b and the lead wire frame 2b are formed from each other at proper intervals at a specified site under each row of leads 21b of the lead wire frame 2b; thereby, a lead wire 5b is connected between a plurality of electrode contacts 11b of the chip 1b and leads 21b of the lead-wire frame 2b, a lead wire 5b′ is connected between at least a lead 21b and a wire bonding area 31b of the metal layer 3b, a mold 6b is used to wrap the chip 1b and the metal layer 3b, and thereby the thin-small sized packaged chip structure according to this invention is formed.

Again, referring now to FIG. 4, according to thin-small sized packaging (including TSOP and QFP) types of this invention, adhesive layers 4c may also be provided below 2 or 4 rows of leads 21c of a lead wire frame 2c to respectively stick to metal layers 3c so that wire bonding areas 31c are reserved on the metal layers, and the chip 1c and the lead wire frame 2c are formed from each other at proper intervals at a specified site under each row of leads 21c of the lead wire frame 2c so that the metal layers 3c are separated from the chip 1c and the lead wire frame 2c; thereby, a lead wire 5c is connected between a plurality of electrode contacts 11c of the chip 1c and leads 21c of the lead-wire frame 2c, at least one electrode contact 11c is selected and connected first to bonding areas 31c of the metal layers 3c with lead wires 5c′ and next to leads 21c with lead wires 5c′, a mold 6c is used to wrap the chip 1c and the metal layers 3b, and thereby the thin-small sized packaged chip structure according to this invention may also be formed.

This invention provides an improvement of the packaged chip structure capable of lowering characteristic impedance, and the metal layers 3 and 3c may be provided under the lead wire frames 2 and 2c (as shown in FIGS. 1 and 4), exactly separated from the chips 1 and 1c and the lead wire frames 2 and 2c, or the metal layers 3a and 3b may be provided above the lead wire frames 2a and 2b (as shown in FIGS. 2 and 3); thereby, the lead wires 5′-5c′ provided are connected between the leads 21-21c and the metal layers 3˜3c (as shown in FIGS. 5 and 6) so that the metal layers 3˜3c may be formed into a Ground plane or a Power plane; if it is implemented, then Ground is connected to lower electrical noises and EMI and to eliminate a problem of poor transmission of signals resulting from characteristic impedance of the packaged body of chip so that the stable transmission of signals and the efficient transmission speed may be further developed.

To sum up, this invention “the packaged chip capable of lowering characteristic impedance” completely meet the requirements of application for the new type patent, and hence we apply following the patent law; we earnestly request you to examine it for details and to approve the patent as soon as possible for protection of the inventor's rights and interests; feel free to contact us if you, the examiner, have any questions at the time of examination.

1. A packaged chip capable of lowering characteristic impedance, comprising a chip, a lead wire frame, metal layers, adhesive layers, lead wires, and a mold, characterized in that:
the adhesive layers are provided under each row of leads of the lead wire frame to stick to metal layers so that wire bonding areas are reserved on the metal layers, and the chip is provided under the metal layers so that the metal layers are located between the lead wire frame and the chip; thereby, lead wires are connected between a plurality of electrode contacts of the chip and the leads of the lead-wire frame, and at least one lead of the lead wire frame is electrically connected to the metal layers so that the packaged chip capable of lowering characteristic impedance is formed.

2. The packaged chip capable of lowering characteristic impedance according to claim 1, wherein the adhesive layers are provided under each row of leads of the lead wire frame to stick to the metal layers, the chip is provided under the lead wire frame, the lead wires are connected between the plurality of electrode contacts of the chip and the leads of the lead-wire frame, and a lead wire is provided and connected between at least one lead of the lead wire frame and a wire bonding area of the metal layer.

3. The packaged chip capable of lowering characteristic impedance according to claim 1, wherein another adhesive layer is provided under the metal layer or the lead wire frame to stick to the chip.

4. The packaged chip capable of lowering characteristic impedance according to 2, wherein another adhesive layer is provided under the metal layer or the lead wire frame to stick to the chip.
